(19) United States
(12) Patent Application Publication
(10) Pub. No.: US 2012/0192937 A1
(43) Pub. Date: Aug. 2, 2012

(54) THIN FILM STRUCTURE FOR PHOTOVOLTAIC APPLICATIONS

(76) Inventors: Mariappan Parans Paranthaman, Knoxville, TN (US); Sung-Hun Wee, Knoxville, TN (US); Frederick A. List, III, Andersonville, TN (US); Claudia Cantoni, Knoxville, TN (US); Lee Heatherly, JR., Jacksboro, TN (US); Kyunghoon Kim, Knoxville, TN (US); Thomas R. Fanning, Boulder, CO (US); Jon Bornstein, Cupertino, CA (US)

(21) Appl. No.: 13/016,460

(22) Filed: Jan. 28, 2011

(51) Int. Cl. H01L 31/02; H01L 31/0368

(52) U.S. Cl. 136/256; 438/97; 257/E31.044

(57) ABSTRACT

A thin film structure for photovoltaic applications includes a biaxially textured metal substrate; a seed layer epitaxially disposed on the metal substrate; a barrier layer comprising SrTiO₃ epitaxially disposed on the seed layer; a cap layer comprising γ-Al₂O₃ epitaxially disposed on the SrTiO₃ barrier layer; and a crystalline silicon layer epitaxially disposed on the cap layer, where the cap layer comprises a volume fraction of biaxial texture of at least about 80% and the crystalline silicon layer does not include a metal silicide phase.

### FEDERALLY SPONSORED RESEARCH OR DEVELOPMENT

The present invention arose in the performance of Prime Contract No. DE-AC05-00OR22725 between UT-Battelle, LLC and the U.S. Department of Energy. The government has certain rights in the invention.

### BACKGROUND

The central challenge of solar energy conversion is the low power density of sunlight at the earth's surface. To compete with fossil-fuel-generated electricity, flat-plate photovoltaic (PV) panels require inexpensive, high-quality, crystalline materials on low-cost substrates. Crystalline silicon has demonstrated manufacturability and accounts for more than 80% of photovoltaic panels today. Such panels are reliable, efficient, and based on a semiconductor made from an inexhaustible raw material. However, the cost of manufacturing silicon wafers is very expensive, amounting to about half the cost of a solar module. The largest crystalline silicon wafer size available at this time is about 12 inches in diameter. Furthermore, there are inefficiencies in utilizing the silicon wafers. Less than 10 microns of silicon are needed to fabricate an efficient solar cell; however, due to sawing losses and difficulties in handling very thin wafers, applications typically use on the order of 150-400 microns of silicon. Crucially, the high cost of wafers means wafer-based modules may not surpass the DOE cost goal of $1/Watt and cannot compete with electricity from traditional fuel sources without subsidies.

In the field of high-temperature superconductors, a great deal of materials research has focused on epitaxial growth of high-temperature superconducting layers on biaxially-textured metal surfaces. Superconducting articles with current densities (J_{c}) in excess of 1 MA/cm² at 77 K have been achieved for epitaxial YBa₂Cu₃O₇ films on biaxially-textured Ni or Ni-based alloy surfaces with the use of certain epitaxial buffer layer constructs between the metal surface and the superconducting layer. In previous work, the synthesis of high-temperature epitaxial superconductor layers capable of carrying a high J_{c} has been achieved with complex, multilayered buffer architectures.

It would be advantageous to be able to grow silicon epitaxially onto a substrate, preferably an inexpensive substrate, with a desirable crystal orientation and other preferred characteristics. High PV efficiencies may be possible with thin silicon layers; for example, adequate light absorption for devices more than 15% efficient can be obtained with a Si thickness of less than 10 microns (compared to ˜200 micron thick Si wafers, with 150 micron kerf loss). If the fabrication of epitaxial silicon layers can be perfected, wafer-like efficiencies may be achieved at area costs comparable to thin film technologies (e.g., amorphous silicon, CdTe, CIGS) and improved PV devices may be realized.

### BRIEF SUMMARY

Described here is a thin film architecture suitable for photovoltaic device applications, as well as a method of making the thin film structure.

The thin film structure includes a biaxially textured metal substrate; a seed layer epitaxially disposed on the metal substrate; a barrier layer comprising SrTiO₃ epitaxially disposed on the seed layer; a cap layer comprising γ-Al₂O₃ epitaxially disposed on the SrTiO₃ barrier layer; and a crystalline silicon layer epitaxially disposed on the cap layer, where the cap layer comprises a volume fraction of biaxial texture of at least about 80% and the crystalline silicon layer does not include a metal silicide phase, such as a nickel or copper silicide phase.

The method comprises forming an epitaxial seed layer on a biaxially textured metal substrate; forming an epitaxial barrier layer comprising SrTiO₃ on the epitaxial seed layer; forming an epitaxial cap layer comprising γ-Al₂O₃ on the epitaxial barrier layer; and forming an epitaxial crystalline silicon layer on the epitaxial cap layer, where the epitaxial barrier layer comprising SrTiO₃ is formed in an oxygen partial pressure of between about 0.1 mTorr and about 200 mTorr.

### BRIEF DESCRIPTION OF THE DRAWINGS

FIG. 1 is a schematic of a thin film structure including a crystalline silicon layer;

FIG. 2 is a schematic of two exemplary buffer layer architectures on biaxially textured nickel substrates;

FIG. 3 shows θ-2θ x-ray diffraction (XRD) scans for γ-Al₂O₃ and STO layers grown on a RABiTS template (Ni—W, 75 μm) with a buffer architecture comprised of CeO₂ (75 nm)/YSZ (75 nm)/Y₂O₃ (75 nm)/NiW (top); for comparison, the XRD result for the RABiTS template is also shown (bottom);

FIG. 4A-4B show ω and φ scans for γ-Al₂O₃, STO, and CeO₂ layers grown on RABiTS template (NiW, 75 μm) with a buffer architecture comprised of CeO₂ (75 nm)/YSZ (75 nm)/Y₂O₃ (75 nm);

FIG. 5 shows θ-2θ XRD scans for γ-Al₂O₃ and STO layers grown on a NiW substrate with a thin MgO layer (top); for comparison, the XRD result for a NiW substrate with a thin MgO layer is also shown in the figure (bottom);

FIG. 6 shows ω and φ scans for γ-Al₂O₃ and STO layers grown on a NiW substrate with a thin MgO layer;

FIGS. 7A and 7B are micrographs from an exemplary PLD γ-Al₂O₃ surface (deposited on SrTiO₃/CeO₂/YSZ/Y₂O₃/Ni-5W) before and after nitric acid etching, respectively;

FIG. 8A is an AFM image of the surface of Sample 6 (see Table 2) after deposition of the seed layer (including sublayers CeO₂/YSZ/Y₂O₃);

FIG. 8B is an AFM image of the surface of Sample 6 after deposition of the STO layer by PLD; and

FIG. 8C is an AFM image of the surface of Sample 6 after deposition of the γ-Al₂O₃ layer by PLD.

### DETAILED DESCRIPTION OF THE DRAWINGS AND THE PRESENTLY PREFERRED EMBODIMENTS

Epitaxial growth of crystalline silicon on a biaxially textured template is proposed as a means of producing a silicon thin film of the desired microstructure for photovoltaic PV applications. Rolling assisted biaxially textured substrates (RABiTS) are metal foils that typically include (100)-oriented, biaxially textured grains of about 50 microns in size with low-angle grain boundaries. The inventors have found that these substrates may be coated with heteroepitaxial buffer layers to transfer the grain size and orientation of the metal foil into a crystalline silicon layer. Accordingly, a high-quality biaxially textured silicon film may be produced on an inexpensive substrate. The inventors believe this alternative silicon PV fabrication technology may be capable of reducing PV module costs to below $0.50/W.

A biaxially textured crystalline silicon film may be defined as a polycrystalline silicon layer having grains that are predominantly crystallo-graphically aligned perpendicular to the plane of the metal substrate (c-axis oriented) and parallel to the plane of the metal substrate (a-b alignment). In addition, the crystallographic in-plane and out-of-plane grain-to-grain misorientations are small (e.g., less than about 10 degrees). The formation of a crystalline silicon film having this orientation starts with a biaxially textured metal substrate and a suitable choice of overlying buffer layers, which serve as a template to transfer the biaxial texture of the substrate to the silicon film. In the present disclosure, a film that is crystallographically consistent with the underlying layer is referred to as an “epitaxial” layer, or as being “epitaxially disposed” on the underlying layer.

The inventors have recognized that selection of the proper buffer layers is important for forming an epitaxial crystalline silicon layer that is optimized for device applications. Without appropriately selected buffer layers and deposition conditions, the thin film structure may have various shortcomings, such as pin-hole defects that allow metal from the substrate to diffuse into the silicon. For example, the inventors recently demonstrated the epitaxial growth of c-Si on a γ-Al₂O₃/MgO/Ni-3W stack (where the layer preceding the “/” is deposited on the layer following the “/”); however, due to the diffusion of nickel from the substrate into the silicon through pin-holes in the oxide layers, nickel silicide (NiSi) towers appeared in the silicon film. Such impurities may prevent the silicon from being used in a device architecture.

The inventors have also discovered that inclusion of a SrTiO₃ layer in the buffer layer stack between a seed layer on the substrate and a γ-Al₂O₃ cap layer is advantageous. Formed under the proper deposition conditions, the SrTiO₃ layer lead to improved texture in the γ-Al₂O₃ layer and thus facilitates the deposition of a high quality crystalline silicon layer. For example, a highly biaxially-textured, epitaxial c-Si layer may be formed on a γ-Al₂O₃/SrTiO₃/CeO₂/YSZ/Y₂O₃/Ni-5W stack, as discussed further below.

Accordingly, described in the present disclosure is a thin film structure including an epitaxial crystalline silicon layer overlying high quality buffer layers on a biaxially-textured metal substrate. A process for fabricating the thin film structure is also described. The buffer layers are substantially pin-hole free, resistant to nickel diffusion, and low in surface roughness, and they include a high volume fraction of biaxial texture. Such layers provide an ideal template for growth of a biaxially textured crystalline Si film that is suitable for photovoltaic and other devices.

Referring to FIG. 1, the thin film architecture 100 includes a biaxially textured metal substrate 105, a seed layer 110 comprising at least one film epitaxially disposed on the metal substrate, a SrTiO₃ barrier layer 115 epitaxially disposed on the seed layer, a γ-Al₂O₃ cap layer 120 epitaxially disposed on the SrTiO₃ barrier layer, and a crystalline silicon layer 125 epitaxially disposed on the γ-Al₂O₃ cap layer, where the cap layer comprises a volume fraction of biaxial texture of at least about 80% and the crystalline silicon layer does not include a metal silicide phase. Advantageously, the volume fraction of biaxial texture is even higher, such as at least about 85%, or at least about 90%, and is passed on to the crystalline silicon layer. Each of the SrTiO₃ barrier layer and the γ-Al₂O₃ cap layer includes crystallographic in-plane and out-of-plane grain-to-grain misorientations of about 10° or less. The misorientations may also be about 8° or less, and they may be less than the misorientations present in the underlying biaxially textured metal substrate.

The biaxially textured metal substrate may include nickel, copper, tungsten and/or another transition metal. For example, the substrate may be a Ni-3W or Ni-5W alloy in the form of flexible nickel-tungsten foil. A description of the fabrication of biaxially textured metal substrates can be found in U.S. Pat. No. 6,375,768, “Method of Making Biaxially Textured Articles by Plastic Deformation,” issued Apr. 23, 2002, which is hereby incorporated by reference in its entirety.

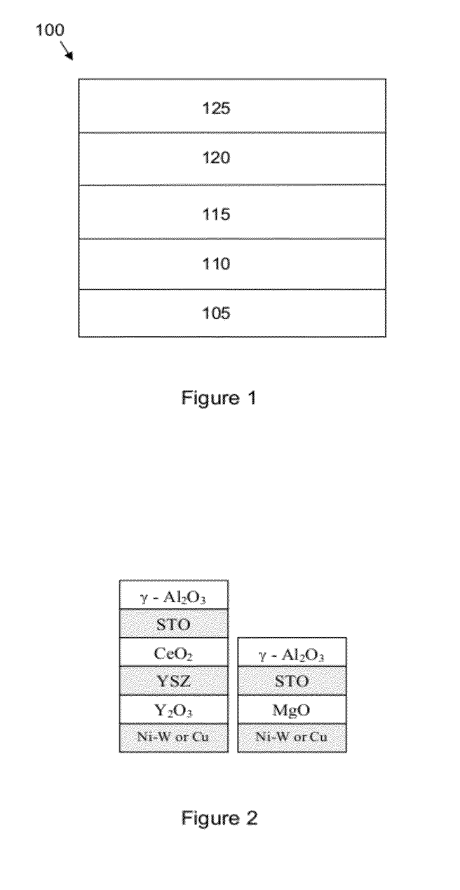

The seed layer may include one or more materials selected from among MgO, TiN, LaMnO₃, La₂Zr₂O₇ (LZO), Y₂O₃, Y₂O₃-stabilized ZrO₂ (YSZ), CeO₂ and other compounds. Exemplary stack architectures are shown in FIG. 2. In some embodiments, the seed layer may have a sublayer structure. For example, the seed layer may include two or more sublayers, such as a first sublayer comprising Y₂O₃, a second sublayer comprising YSZ on the first sublayer, and a third sublayer comprising CeO₂ on the second sublayer. Typically, the seed layer has a total thickness of between about 75 nm and about 300 nm. When sublayers are present, each sublayer may have a thickness of between about 50 nm and about 100 nm. Ideally, the seed layer is substantially free of pin-hole defects.

The seed layer may be formed by a physical vapor deposition (PVD) technique, such as sputtering, electron beam evaporation, or pulsed laser deposition. The deposition may be carried out using one or more metal/alloy targets in a reactive gas environment (e.g., oxygen or nitrogen) in order to form the desired seed layer composition.

An epitaxial γ-Al₂O₃ top (or cap) layer has been found to be effective in depositing an epitaxial Si film on a RABiTS template. Ideally, such a layer can be successfully deposited on a RABiTS template with a buffer architecture comprised of CeO₂/YSZ/Y₂O₃, a thin film structure that was developed for epitaxial growth of YBa₂Cu₃O_{7δ} superconducting films. In practice, however, epitaxial growth of a γ-Al₂O₃ layer on a CeO₂ layer is generally unsuccessful. The inventors have discovered that epitaxial growth of the γ-Al₂O₃ film may be achieved by first depositing a SrTiO₃ (STO) barrier layer on the CeO₂ and then depositing the γ-Al₂O₃ cap layer. For the γ-Al₂O₃ cap layer to have the desired characteristics, including high density and a high volume fraction of biaxial texture, the STO barrier layer is desirably formed under a set of optimized conditions, as discussed below. The STO barrier and γ-Al₂O₃ cap layers may be deposited using any of a variety of vapor deposition techniques, although pulsed laser deposition is advantageous to grow the layers highly epitaxial and dense. Typically, the thickness of each of the STO layer and the γ-Al₂O₃ layer is between about 10 nm and about 300 nm. The thickness of each layer may also lie between about 50 nm and about 300 nm.

An additional barrier layer including a nickel oxide phase (e.g., NiO, NiWO₄) may be formed intentionally or unintentionally between the metal substrate and the seed layer. Such phases may be effective in blocking nickel diffusion through the stack. The additional barrier layer may be formed by oxidation of the nickel-based substrate during deposition of the barrier (SrTiO₃) or cap (γ-Al₂O₃) layer. Typically the additional barrier layer is between about 10 nm and 100 nm in thickness and is not necessarily epitaxially oriented with respect to the underlying metal substrate.

A method of making a thin film device that may include the above-described layers includes forming an epitaxial seed layer on a biaxially textured metal substrate. As described above, the seed layer may include a plurality of sublayers. An epitaxial barrier layer comprising SrTiO₃ is formed on the epitaxial seed layer, and an epitaxial cap layer comprising γ-Al₂O₃ is formed on the SrTiO₃ barrier layer. All layers can be grown in an oxygen partial pressure that lies between about 1×10⁻⁷ Torr and 200 mTorr. An oxygen partial pressure between about 0.1 mTorr and 200 mTorr is preferred for deposition of the SrTiO₃ barrier layer and the γ-Al₂O₃ layer. The oxygen partial pressure may also be between about 0.1 mTorr and 100 mTorr or about 10 mTorr and 200 mTorr.

Both the barrier layer and the cap layer may be formed by pulsed laser deposition. The pulsed laser deposition may be carried out at a laser energy density of between about 1 J/cm² and about 10 J/cm² and for between about 1,000 and about 20,000 laser pulses, where the number of pulses determines the thickness of the resulting layer in the range of about 50-300 nm. For the SrTiO₃ layer, a laser energy density of between about 2 J/cm² and about 5 J/cm² may be particularly advantageous. Finally, an epitaxial crystalline silicon layer is formed on the γ-Al₂O₃ cap layer by, for example, hot-wire chemical vapor deposition (CVD). The crystalline silicon and other layers may be formed at a substrate temperature of between about 600° C. and 900° C. The substrate temperature may also lie between about 600° C. and 800° C., or 600° C. and 700° C.

### Example 1

### Epitaxial Growth of STO and γ-Al₂O₃ Layers on RABiTS Templates

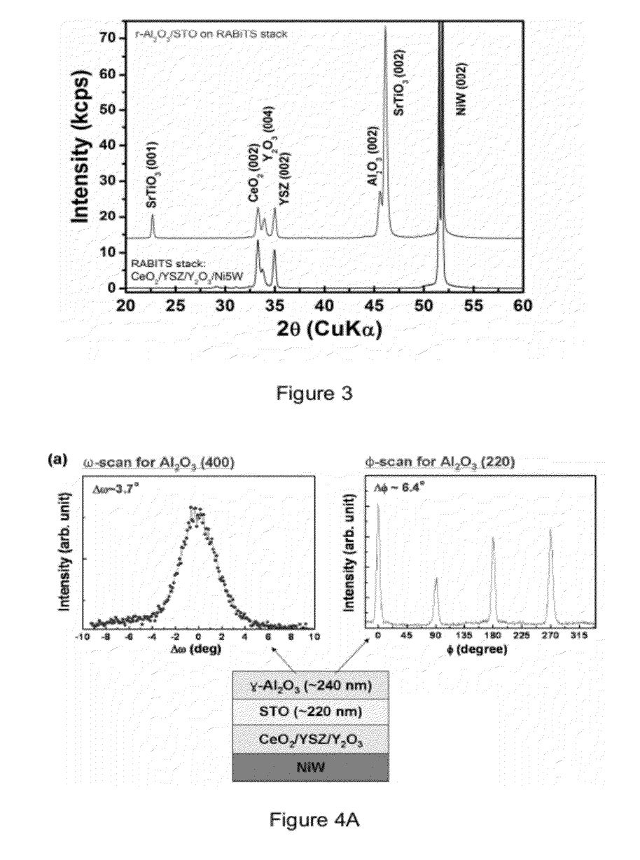

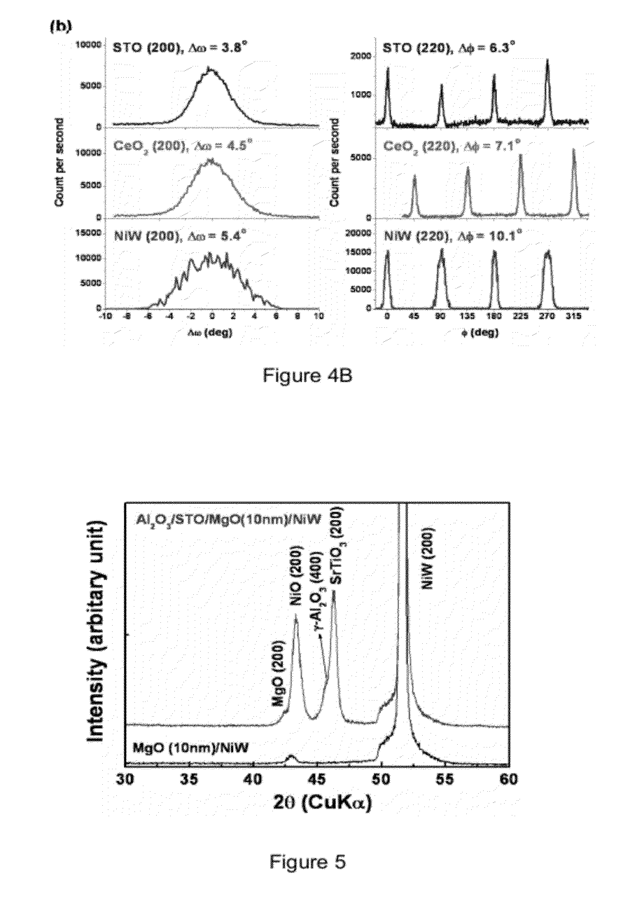

Exemplary PLD conditions for epitaxial growth of STO and γ-Al₂O₃ layers CeO₂ (75 nm)/YSZ (75 nm)/Y₂O₃ (75 nm)/NiW (75 μm) are summarized in Table 1. The 8-28 x-ray diffraction result (FIG. 3) shows strong STO and γ-Al₂O₃ (h00) peaks with no peaks related to other orientations. The ω and φ scans for the sample (FIG. 4A-4B) also show that the γ-Al₂O₃ and STO films have smaller full-width-half-maximum values (Δω and Δφ), indicating that these layers have excellent cube-on-cube epitaxy with improved in-plane and out-of-plane textures, compared to a CeO₂ layer and NiW substrate, for which data are also displayed in the figure.

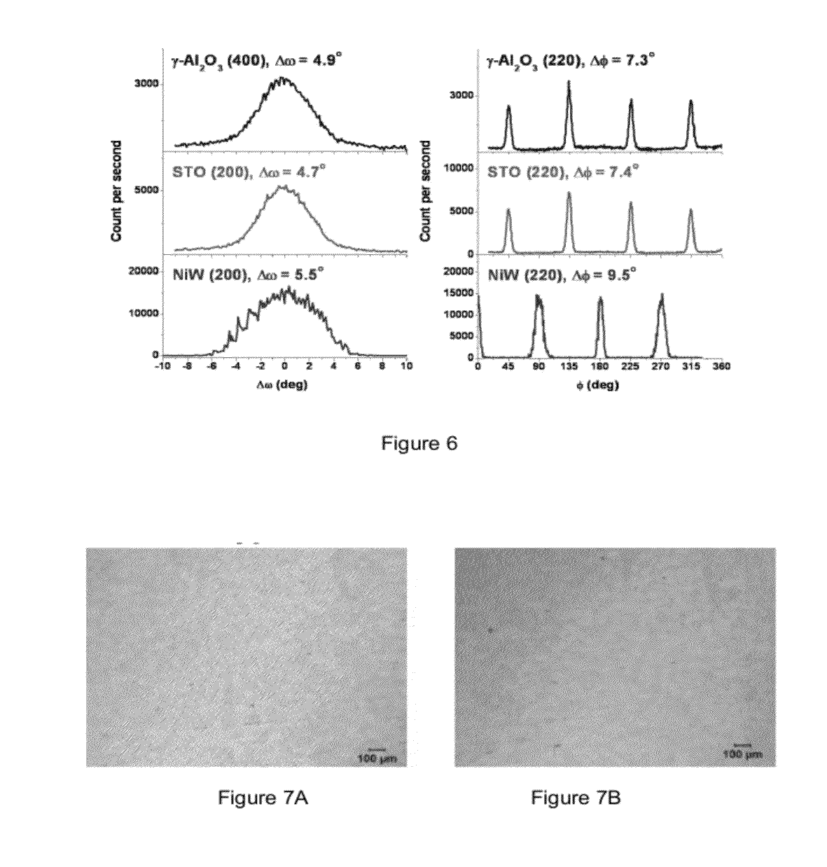

Epitaxial growth of γ-Al₂O₃ and STO layers also has been achieved on a biaxially-textured NiW substrate with a single MgO layer as the seed layer (MgO (˜10 nm)/NiW (75 μm)) by PLD. The epitaxial MgO thin layer was directly deposited on the NiW substrate by e-beam deposition. The XRD results (FIGS. 5 and 6) including θ-2θ scans, ω and φ scans show that STO and γ-Al₂O₃ layers are epitaxially grown with excellent in-plane and out-of-plane textures, which are better than those for the NiW substrate. The θ-2θ scan also reveals that a NiO phase is formed between the NiW substrate and the MgO seed layer during the STO film growth. Since the layer may be a beneficial layer to help block Ni diffusion, the STO growth condition is also tuned to form deliberately the oxide layer during growth.

TABLE 1
PLD growth conditions for γ-Al₂O₃
and STO layers on RABiTS template

| | γ-Al₂O₃ | | STO film | |
|---|---|---|---|---|
| Laser energy density | 3-4 | J/cm² | 2-3 | J/cm² |
| Repetition rate | 10 | Hz | 10 | Hz |
| Target-substrate distance | 5-7 | cm | 5-7 | cm |
| Processing gas | Pure O₂ gas | | Pure O₂ gas | |
| Substrate temperature | 650-700° | C. | 600-800° | C. |
| Deposition pressure | 10 | mTorr | 10-200 | mTorr |
| Film thickness | ~240 | nm | 220 | nm |

### Example 2

### Optimization of Pulsed Layer Deposition Conditions

Pulsed laser deposition (PLD) conditions for fabricating epitaxial SrTiO₃ and γ-Al₂O₃ films on CeO₂/YSZ/Y₂O₃/Ni-5W have been optimized, where the Ni-5W is a RABiTS metal foil. The optimized layers have further been employed to successfully fabricate solar cells.

TABLE 2
Deposition Conditions for SrTiO₃ Layer on CeO₂/YSZ/Y₂O₃/ Ni—5W

| | | | | | | | | X-ray |
|---|---|---|---|---|---|---|---|---|
| SrTiO₃ | Depo- | | | | | | Film | Cube |
| (STO) | sition | Oxygen | Laser | Laser | γ-Al₂O₃ | Nitric | Surface | Texture |
| Process | Temp. | pressure | Energy | Shots | Deposi- | Acid | Roughness | Volume |
| conditions | (° C.) | (Torr) | (J/cm²) | (Ea) | tion | Test | (nm) | Fraction |
| Sample 1 | 650 | 1.0 × 10⁻³ | 4.5 | 5,000 | | | | |
| (STO | | | | | | | | |
| DOE1) | | | | | | | | |
| Sample 2 | 850 | 1.0 × 10⁻³ | 2.3 | 5,000 | | | | |
| (STO | | | | | | | | |
| DOE2) | | | | | | | | |
| Sample 3 | 650 | 2.0 × 10⁻¹ | 2.3 | 5,000 | Yes | | | 56.8 |
| (STO | | | | | | | | |
| DOE3) | | | | | | | | |
| Sample 4 | 850 | 2.0 × 10⁻³ | 4.5 | 5,000 | Yes | | | 44.7 |
| (STO | | | | | | | | |
| DOE4) | | | | | | | | |
| Sample 5 | 650 | 1.0 × 10⁻³ | 4.5 | 15,000 | Yes | Passed | | 91.6 |
| (STO | | | | | | | | |
| DOE5) | | | | | | | | |
| Sample 6 | 650 | 1.0 × 10⁻³ | 6.5 | 5,000 | Yes | | 3.11 | 89.5 |
| (STO | | | | | | | | |
| DOE6) | | | | | | | | |
| Sample 7 | 650 | Vacuum | 4.5 | 5,000 | Yes | | | 58.2 |
| (STO | | | | | | | | |
| DOE7) | | | | | | | | |
| Sample 8 | 650 | 1.0 × 10⁻³ | 6.5 | 15,000 | Yes | | | <40 |
| (STO | | | | | (in-situ) | | | |
| DOE8) | | | | | | | | |

The data in Table 2 provide pulsed laser deposition conditions, including substrate temperature, oxygen partial pressure, laser energy density, and laser shots (pulses) for SrTiO₃ (STO) layers formed on CeO₂/YSZ/Y₂O₃/Ni-5W stacks. The table also indicates for the eight samples (STO DOE 1 to STO DOE 8) whether or not a γ-Al₂O₃ film was deposited on the STO layer, and whether or not an acid test (described below) was carried out and passed. The last columns indicate the volume fraction of biaxial texture in the γ-Al₂O₃ layer deposited on the STO layer, and also the surface roughness of the γ-Al₂O₃ layer.

As can be seen in Table 2, the STO layers in this example were deposited at a substrate temperature of either 650° C. or 850° C. The O₂ partial pressure was either 10 mTorr, 200 mTorr, or negligible (“vacuum”). The laser energy density ranged from 2.3 J/cm² to 6.5 J/cm², and 5,000 or 15,000 shots (laser pulses) were employed to build up the layer. XRD data, including θ-2θ scans, ω and φ scans, and pole figures, were obtained after deposition of the γ-Al₂O₃ layer to characterize the thin film stack and evaluate the quality of the biaxial texture.

Deposition of the γ-Al₂O₃ layer did not proceed on Samples 1 and 2 (STO DOE 1 and STO DOE 2), but a γ-Al₂O₃ layer was deposited on Samples 3 through 8 (STO DOE 3 through STO DOE 8). Samples 3, 4, and 7, which were exposed to an oxygen partial pressure of 200 mTorr or vacuum during deposition of the STO film, each showed a nonoptimal volume fraction of biaxial texture in the γ-Al₂O₃ layer; volume fractions of 56.8%, 44.7%, and 58.2%, respectively, were obtained from the XRD pole figure analysis. In contrast, Samples 5 and 6, which were exposed to an oxygen partial pressure of 10 mTorr during STO deposition, achieved much higher volume fractions of biaxial texture, specifically, 91.6% and 89.5%, respectively. During the sample 8 growth, both STO and γ-Al₂O₃ layers were grown simultaneously in a single run using pulsed laser deposition without breaking the vacuum. However, samples 1 through 7, both STO and γ-Al₂O₃ layers were deposited in separate runs. Hence, in sample 8, STO layers may have oxygen defects. That could be the reason for the reduced % texture in sample 8.

### Example 3

### Nitric Acid Tests of Buffer Layer Architectures

To determine whether or not the buffer layer stacks included any pin-hole defects or cracks that could allow nickel to diffuse from the substrate to the crystalline silicon layer, nitric acid (HNO₃) etch tests were carried out on a number of different stacks. The etch tests entail depositing a droplet of concentrated nitric acid on the top surface of the stack of interest. After 3 minutes, the top and bottom surfaces of the sample are rinsed with deionized water for about 20 seconds each. The stack is then dried with a nitrogen gun or duster. Because nickel is reactive with nitric acid, its presence on the top surface of the stack may be detected after etching. If no infiltration of nickel is observed after etching, the stack is said to have passed the test and to be substantially free of pin-hole defects. Micrographs from an exemplary PLO γ-Al₂O₃ surface (deposited on SrTiO₃/CeO₂/YSZ/Y₂O₃/Ni-5W) before and after etching are shown in FIGS. 7A and 7B, respectively.

The inventors have fabricated a number of buffer layer stacks that are substantially pin-hole free and resistant to nickel diffusion. Exemplary buffer layer architectures (on nickel substrates) that have passed the nitric acid test include: γ-Al₂O₃/SrTiO₃/CeO₂/YSZ/Y₂O₃/Ni-5W formed using pulsed laser deposition; LaMnO₃/Ni-3W, formed using sputtering; TiN/Ni-5W, formed using pulsed laser deposition; TiN/Ni-5W, formed using sputtering; LZO/Ni—W, formed using solution deposition; and Y₂O₃/Ni—W, formed using sputtering; TiN/MgO/Cu, formed using sputtering.

### Example 4

### Surface Roughness Evaluations

Atomic force microscopy (AFM) was employed to evaluate the surface roughness of the layers deposited on a nickel substrate. A low surface roughness is beneficial because it has the potential to reduce the defect density in the heteroepitaxial silicon layer. Generally, the surface roughness is about 10 nm or less, and a surface roughness of about 5 nm or less is desired. Under ideal processing conditions, a surface roughness of about 3 nm or less is achievable for the layers.

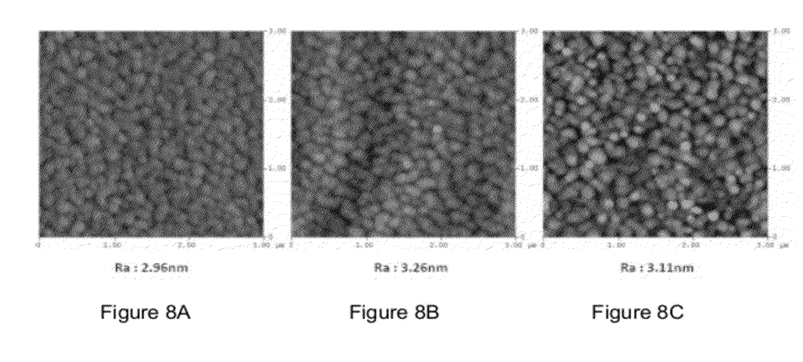

FIG. 8A is an AFM image of the surface of Sample 6 after deposition of the seed layer (including sublayers CeO₂/YSZ/Y₂O₃); FIG. 8B is an AFM image of the surface of Sample 6 after deposition of the STO layer by PLD; and FIG. 8C is an AFM image of the surface of Sample 6 after deposition of the γ-Al₂O₃ layer by PLD. Surface roughness values (Rₐ) of 2.96 nm, 3.26 nm, and 3.11 nm were obtained, respectively, for the surfaces of FIGS. 8A, 8B, and 8C.

Although the present invention has been described in considerable detail with reference to certain embodiments thereof, other embodiments are possible without departing from the present invention. The spirit and scope of the appended claims should not be limited, therefore, to the description of the preferred embodiments contained herein. All embodiments that come within the meaning of the claims, either literally or by equivalence, are intended to be embraced therein. Furthermore, the advantages described above are not necessarily the only advantages of the invention, and it is not necessarily expected that all of the described advantages will be achieved with every embodiment of the invention.

1. A thin film structure for photovoltaic applications, the thin film structure comprising:
a biaxially textured metal substrate;
a seed layer epitaxially disposed on the metal substrate;
a barrier layer comprising SrTiO₃ epitaxially disposed on the seed layer;
a cap layer comprising γ-Al₂O₃ epitaxially disposed on the SrTiO₃ barrier layer; and
a crystalline silicon layer epitaxially disposed on the cap layer,
wherein the cap layer comprises a volume fraction of biaxial texture of at least about 80% and the crystalline silicon layer does not include a metal silicide phase.

2. The thin film structure of claim 1 wherein the volume fraction of biaxial texture is at least about 85%.

3. The thin film structure of claim 1 wherein the biaxially textured metal substrate comprises a metal selected from the group consisting of nickel, copper, tungsten, iron, molybdenum, and vanadium.

4. The thin film structure of claim 3 wherein the metal silicide phase comprises one of nickel silicide and copper silicide.

5. The thin film structure of claim 3 wherein the metal substrate comprises one of Ni-3W and Ni-5W.

6. The thin film structure of claim 1 wherein an additional barrier layer comprising a nickel oxide phase is disposed between the metal substrate and the seed layer.

7. The thin film structure of claim 1 wherein the seed layer is substantially free of pin-hole defects.

8. The thin film structure of claim 1 wherein the seed layer comprises one or more materials selected from the group consisting of: MgO, TiN, LaMnO₃, Y₂O₃, YSZ, and CeO₂.

9. The thin film structure of claim 1 wherein the seed layer comprises two or more sublayers.

10. The thin film structure of claim 9 wherein the seed layer comprises:
a first sublayer comprising Y₂O₃;
a second sublayer comprising YSZ on the first sublayer; and
a third sublayer comprising CeO₂ on the second sublayer.

11. The thin film structure of claim 1 wherein a thickness of the seed layer is between about 75 nm and about 300 nm.

12. The thin film structure of claim 1 wherein a thickness of each of the barrier layer and the cap layer is between about 10 nm and 300 nm.

13. The thin film structure of claim 1 wherein each of the barrier layer and the cap layer includes crystallographic in-plane and out-of-plane grain-to-grain misorientations of about 8 degrees or less.

14. The thin film structure of claim 13 wherein the crystallographic in-plane and out-of-plane grain-to-grain misorientations are about 6 degrees or less.

15. The thin film structure of claim 1 wherein the cap layer comprises a surface roughness Rₐ of about 5 nm or less.

16. A method of making a thin film structure, the method comprising:
forming an epitaxial seed layer on a biaxially textured metal substrate;
forming an epitaxial barrier layer comprising SrTiO₃ on the epitaxial seed layer;
forming an epitaxial cap layer comprising γ-Al₂O₃ on the epitaxial barrier layer; and
forming an epitaxial crystalline silicon layer on the epitaxial cap layer,
wherein the epitaxial barrier layer comprising SrTiO₃ is formed in an oxygen partial pressure of between about 0.1 mTorr and about 200 mTorr.

17. The method of claim 16 wherein the epitaxial cap layer is formed in an oxygen partial pressure of between about 0.1 mTorr and about 100 mTorr.

18. The method of claim 16 wherein forming at least one of the epitaxial barrier layer and the epitaxial cap layer comprises pulsed laser deposition.

19. The method of claim 18 wherein the pulsed laser deposition is carried out at a laser energy density of between about 1 J/cm² and about 10 J/cm².

20. The method of claim 16 wherein the epitaxial barrier layer is formed at a substrate temperature of between about 300° C. and 900° C.
